(19) United States
(12) Patent Application Publication
(10) Pub. No.: US 2013/0138368 A1
(43) Pub. Date: May 30, 2013

(54) POWER CONSUMPTION DISPLAY APPARATUS AND POWER CONSUMPTION DISPLAY METHOD

(71) Applicant: Masaki TAKAKURA, Osaka (JP)

(72) Inventor: Masaki TAKAKURA, Osaka (JP)

(73) Assignee: SHARP KABUSHIKI KAISHA, Osaka (JP)

(21) Appl. No.: 13/611,490

(22) Filed: Sep. 12, 2012

(30) Foreign Application Priority Data
Nov. 25, 2011 (JP) 2011-257282

(51) Int. Cl. G06F 19/00; G01R 21/00

(52) U.S. Cl. 702/62

(57) ABSTRACT

A power consumption display apparatus is comprised of a portion for estimating a clock-in time and a clock-out time of a worker involved in a load based on power consumption data obtained by measuring electric power supplied to the load for a certain period to calculate an average clock-in time and an average clock-out time of the worker using the estimated value; a portion for calculating average power consumption of the load during working hours a day based on the power consumption data, the average clock-in time and the average clock-out time; and a portion for calculating target power consumption of the load reduced at a predetermined rate from the average power consumption, in which a measurement value of power consumption per day of the load is graphically displayed together with the average clock-in time the average clock-out time and the target power consumption.

### CROSS-NOTING PARAGRAPH

This non-provisional application claims priority under 35 U.S.C. §119 (a) on Patent Application No. 2011-257282 filed in JAPAN on Nov. 25, 2011, the entire contents of which are hereby incorporated herein by reference.

### FIELD OF THE INVENTION

The present invention relates to a power consumption display apparatus and a power consumption display method for graphically displaying a measured value of power consumption.

### BACKGROUND OF THE INVENTION

Conventionally, in order to reduce electrical usage, analysis has been performed as to whether electricity is not wastefully consumed by measuring individual power consumption with use of a power measurement tap to be graphed.

The power measurement tap for measuring instantaneous power and electric energy of electricity used has been known for obtaining instantaneous power as an average value for each constant time interval by means of a microcomputer with detected voltage and current subjected to digital conversion, followed by integration of such instantaneous power, to calculate electric energy.

Generally, in the case of graphing a measured numerical value, overlaying a target value on a graph to be displayed allows understanding at a glance as to whether to exceed or not to exceed the target value, which is convenient. Conventionally, in the case of graphing power consumption, as disclosed in Japanese Laid-Open Patent Publication No. 2000-193695, a method has been common for setting a numerical value as a target of power consumption in advance to overlay the value on a graph to be displayed.

However, with the method disclosed in Japanese Laid-Open Patent Publication No. 2000-193695, it is possible to grasp a scale of power consumption, however, it is difficult to understand what kind of action leads to increase in power consumption in a status of daily power usage.

Further, a target value of power consumption is greatly different depending on equipment used or a status of use individually. Therefore, an increased number of individuals for measurement causes time-consuming setting of a target value, which poses a problem.

### SUMMARY OF THE INVENTION

An object of the present invention is to provide a power consumption display apparatus and a power consumption display method in which it is possible to grasp a cause of increase in power consumption at the time of displaying power consumption, and setting of a target value for suppressing power consumption does not take a lot of trouble.

An object of the present invention is to provide a power consumption display method comprising the steps of: estimating a clock-in time and a clock-out time of a worker involved in a load from a change in power consumption per day based on power consumption data which is obtained by measuring electric power supplied to the load for a certain period to calculate an average clock-in time and an average clock-out time of the worker in a predetermined period of time using the estimated value; calculating average power consumption of the load during working hours a day in the predetermined period of time based on the power consumption data as well as the average clock-in time and the average clock-out time; calculating target power consumption of the load reduced at a predetermined rate from the average power consumption; and graphically displaying a measurement value of power consumption per day of the load together with the average clock-in time and the average clock-out time as well as the target power consumption that are calculated.

Another object of the present invention is to provide a power consumption display apparatus comprising: a clock-in/out time calculation portion for estimating a clock-in time and a clock-out time of a worker involved in a load from a change in power consumption per day based on power consumption data which is obtained by measuring electric power supplied to the load for a certain period to calculate an average clock-in time and an average clock-out time of the worker in a predetermined period of time using the estimated value; an average power calculation portion for calculating average power consumption of the load during working hours a day in the predetermined period of time based on the power consumption data as well as the average clock-in time and the average clock-out time; a target power calculation portion for calculating target power consumption of the load reduced at a predetermined rate from the average power consumption; and a display portion for graphically displaying a measurement value of power consumption per day of the load together with the average clock-in time and the average clock-out time as well as the target power consumption that are calculated.

### BRIEF DESCRIPTION OF THE DRAWINGS

FIG. 1 is a diagram schematically showing a structural example of an electric power consumption display system including a power consumption display apparatus of the present invention;

FIG. 2 is a block diagram showing an exemplary internal configuration of the power consumption display apparatus of FIG. 1;

FIG. 3 is a diagram showing a structural example of a power measurement tap of FIG. 1:

FIG. 4A and FIG. 4B are diagrams explaining an example of power consumption data that is sent from the power measurement tap to the power consumption display apparatus of FIG. 1;

FIG. 5 is a diagram explaining an example of aggregate power consumption data in which the power consumption display apparatus of FIG. 1 aggregates power consumption data received from all power measurement taps;

FIG. 6 is a diagram showing an example of graph display of power consumption by the power consumption display apparatus of FIG. 1;

FIG. 7 is a flowchart explaining an example of graph display processing by the power consumption display apparatus of FIG. 1;

FIG. 8 is a flowchart explaining an example of estimation processing of a clock-in time and a clock-out time performed by a clock-in/out time calculation portion of FIG. 2;

FIG. 9A and FIG. 9B are diagrams showing an example of a transition of daily power consumption in a case where the clock-in/out time calculation portion of FIG. 2 is not able to estimate a clock-in time and a clock-out time; and

FIG. 10 is a flowchart explaining an example of calculation processing of an average clock-in time and an average clock-out time performed by the clock-in/out time calculation portion of FIG. 2.

### PREFERRED EMBODIMENTS OF THE INVENTION

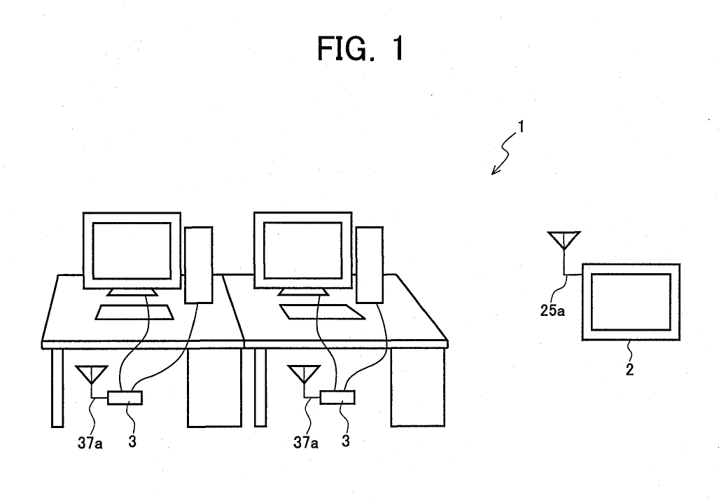

FIG. 1 is a diagram schematically showing a structural example of an electric power consumption display system including a power consumption display apparatus of the present invention.

The electric power consumption display system illustrated by a referential numeral 1 in FIG. 1 is provided with a power consumption display apparatus (hereinafter, abbreviated as a display apparatus) 2 graphically displaying power consumption of a load such as a personal computer, and a power measurement tap 3 supplying electricity to the load as well as measuring the electricity.

The display apparatus 2 and the power measurement tap 3 have built-in radio antennas 25a and 37a, respectively, and power consumption data is sent from the power measurement tap 3 to the display apparatus 2 by radio communication via the radio antennas 25a and 37a. In the display apparatus 2, electric power consumption is displayed based on the power consumption data.

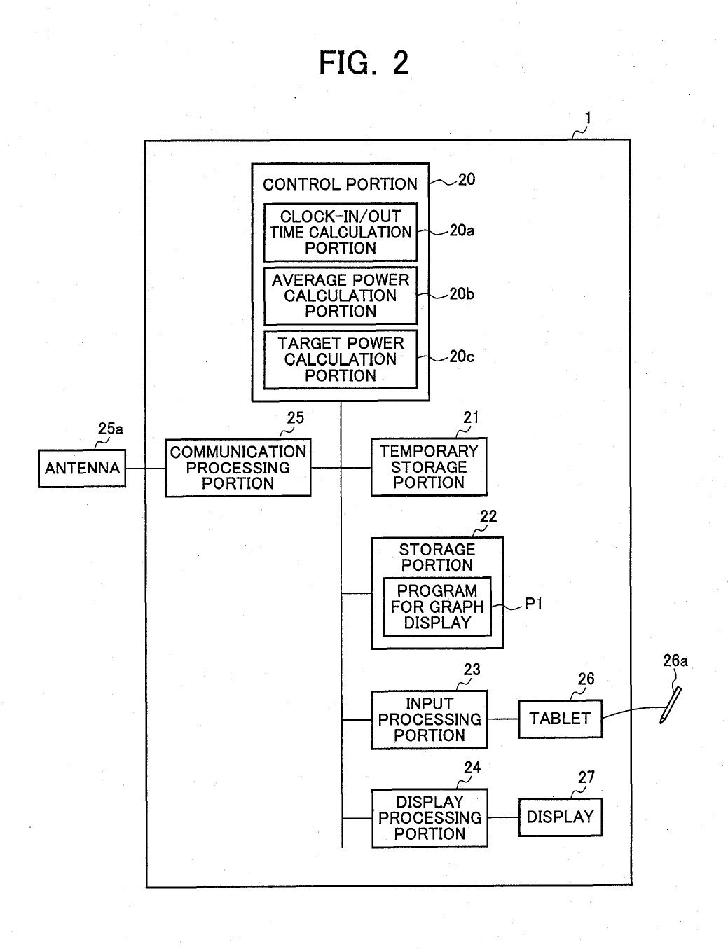

FIG. 2 is a block diagram showing an exemplary internal configuration of the display apparatus 2 of FIG. 1.

The display apparatus 2 is provided with a control portion 20, a temporary storage portion 21, a storage portion 22, an input processing portion 23, a display processing portion 24, a communication processing portion 25, a tablet 26 and a display 27. Note that, the display apparatus 2 may be an apparatus dedicated for display of power consumption, or a general-purpose personal computer.

The control portion 20 uses a CPU (Central Processing Unit) to read to the temporary storage portion 21 and execute various programs such as a program P1 for graph display that is stored in the storage portion 22, thereby controlling operation of each portion of the display apparatus 2.

Note that, a clock-in/out time calculation portion 20a, an average power calculation portion 20b and a target power calculation portion 20c included in the control portion 20 will be described below.

For the temporary storage portion 21, a RAM (Static Random Access Memory), for example, a SRAM (Static RAM) or a DRAM (Dynamic RAM) is used. In the temporary storage portion 21, a program read as described above is stored, while information generated by processing of the control portion 20 is stored.

For the storage portion 22, a hard disk, an SSD (Solid State Drive) or the like is used. In the storage portion 22, the program P1 for graph display is stored. Additionally, another application software program in a graph display apparatus 1 may of course be stored.

To the input processing portion 23, the tablet 26 for receiving input with a pen 26a is connected. The input processing portion 23 receives information such as information of pressing a button that is input by operation of a user of the display apparatus 2 and information of a coordinate showing a position on a screen, and sends such information to the control portion 20.

To the display processing portion 24, the display 27 using a liquid crystal display or the like is connected. The display 27 corresponds to a “display portion” of the present invention. The control portion 20 outputs an application screen for graph display of electric power consumption onto the display 27 via the display processing portion 24 and displays an image in the application screen.

To the communication processing portion 25, the radio antenna 25a is connected for performing radio communication. Note that, for a communication protocol for sending and receiving power consumption data by the radio antenna 25a, a protocol such as ZigBee may be used. The communication protocol is not limited thereto.

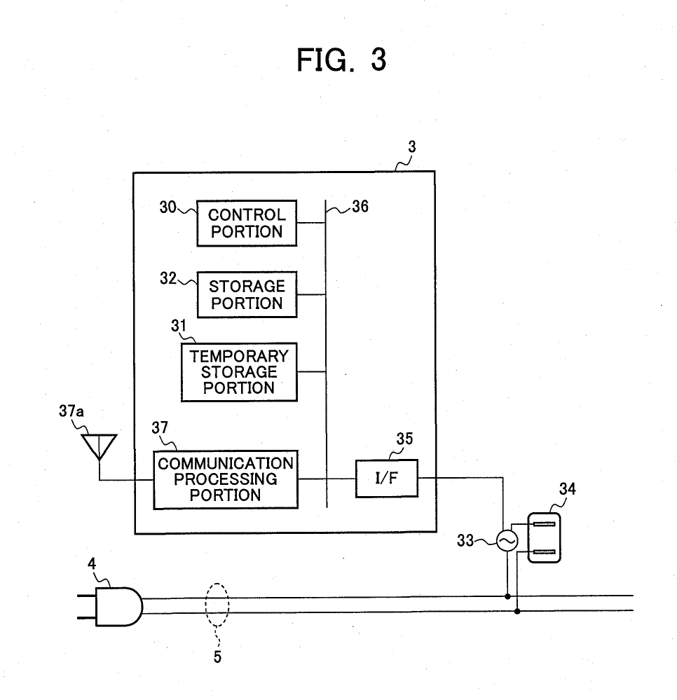

FIG. 3 is a diagram showing a structural example of the power measurement tap 3 of FIG. 1.

The power measurement tap 3 is provided with a control portion 30, a temporary storage portion 31, a storage portion 32, an ammeter 33, an outlet 34, an interface circuit (I/F) 35, an internal bus 36 and a communication processing portion 37.

The control portion 30 reads to the temporary storage portion 31 and executes a program that is stored in the storage portion 32, thereby controlling operation of each portion of the power measurement tap 3.

For the temporary storage portion 31, a RAM is used. In the storage portion 32, a program that is read as described above is stored, while information that is generated by processing of the control portion 30 is stored. For the storage portion 32, a ROM (Read Only Memory) or the like is used.

To the power measurement tap 3, electricity is supplied by a power plug 4. Electricity runs through an electric power line 5, and passes through the ammeter 33 to be supplied to the outlet 34. A measurement value which is obtained with the ammeter 33 and subjected to digital conversion is transferred to the internal bus 36 through the interface circuit 35 of the ammeter.

To the communication processing portion 37, the radio antenna 37a is connected.

In such the power measurement tap 3, the control portion 30 generates power consumption data in which the ammeter 33 is used to measure electricity that is supplied to a load for each predetermined period of time (for example, per second) over a certain period of time (for example, one day), and sends the power consumption data to the display apparatus 2 via the radio antenna 37a.

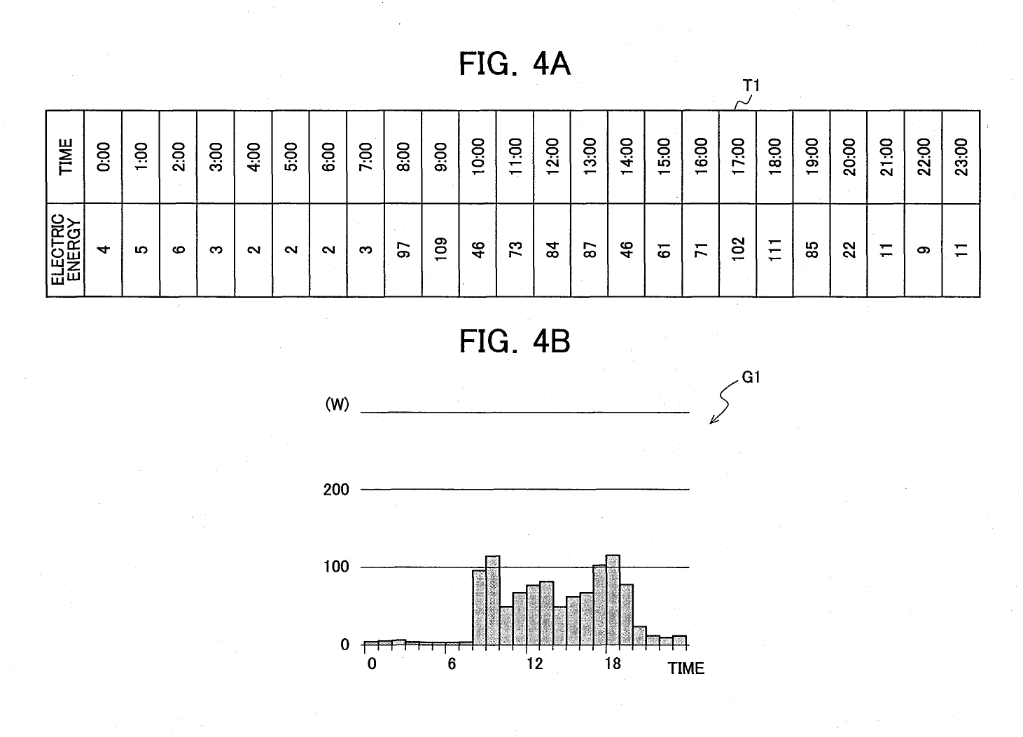

FIG. 4A and FIG. 4B are diagrams explaining an example of power consumption data that is sent from the power measurement tap 3 to the display apparatus 2. FIG. 4A shows a numerical value in a table form, in which, in power consumption data, that is, a table T1, a time is indicated for each hour between 0:00 and 23:00 in a first row, and power consumption (unit: Wh) in the time given (one hour) is indicated in a second row. A graph G1 of FIG. 4B illustrates power consumption data of FIG. 4A graphically.

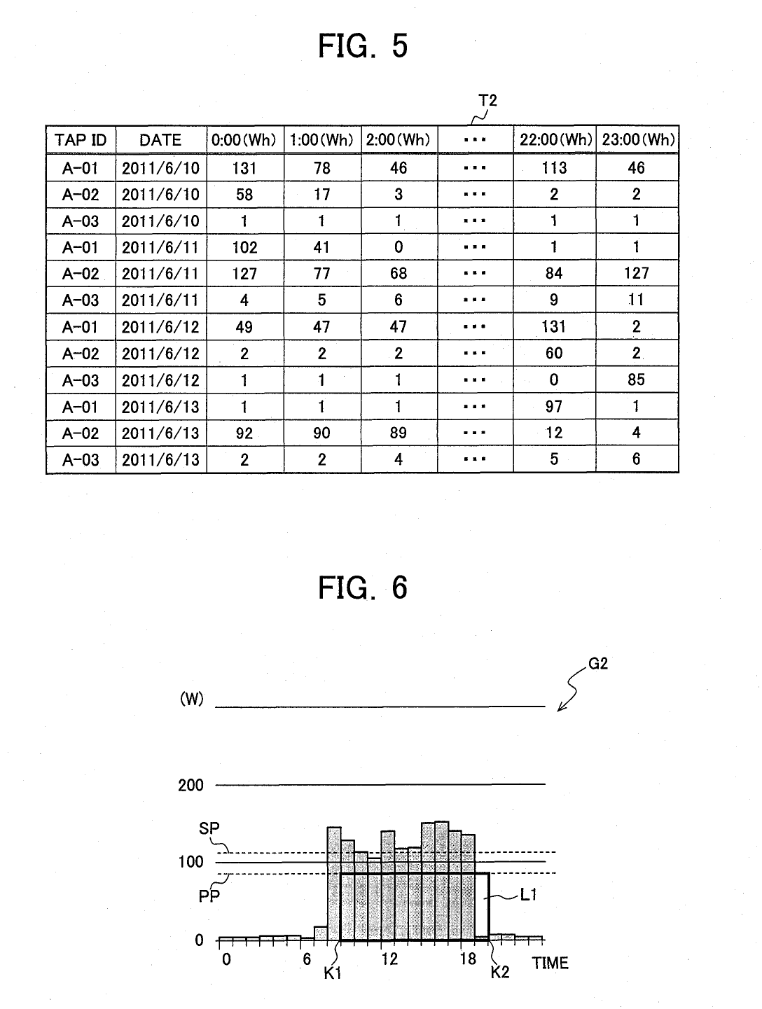

FIG. 5 is a diagram explaining an example of aggregate power consumption data in which the display apparatus 2 aggregates power consumption data received from all power measurement taps 3. In the aggregate power consumption data of FIG. 5, that is a table T2, a specific number of the power measurement tap 3 is indicated in a first column, a date when electricity was measured is indicated in a second column and power consumption (unit: Wh) is indicated in a third column and subsequent columns. In this example, data of three power measurement taps has been aggregated for four days.

In the display apparatus 2, based on the aggregate power consumption data illustrated in FIG. 5, for each load, for example, for each power measurement tap 3, graph display of power consumption is performed.

At the time, the clock-in/out time calculation portion 20a estimates a clock-in time and a clock-out time of a worker involved in the power measurement tap 3 with a change in daily power consumption for the corresponding power measurement tap 3 based on the aggregate power consumption data, and calculates with the estimated value an average clock-in time and an average clock-out time of the above worker during a predetermined period of time (for example, four days).

Further, the average power calculation portion 20b calculates average power consumption of the corresponding power measurement tap 3 during working hours a day in a predetermined period of time based on a reference clock-in time on the basis of the average clock-in time as well as a reference clock-out time on the basis of the average clock-out time and power consumption data for outputting as reference power consumption. More specifically, with “average clock-in time”=“reference clock-in time” and “average clock-out time”=“reference clock-out time”, the average power calculation portion 20b first calculates an average value of daily power consumption in the predetermined period of time of the corresponding power measurement tap 3, and the above-described average value of daily power consumption is divided by average working hours obtained by “reference clock-out time”−“reference clock-in time”, so that the above-described average power consumption is calculated to be output as the reference power consumption.

Moreover, the target power calculation portion 20c calculates target power consumption reduced at a predetermined rate from the reference power consumption.

Then, the display apparatus 2 overlays and displays the reference clock-in time, the reference clock-out time and the target power consumption on the display 27 for graph display of power consumption. The reference power consumption is also overlaid thereon to be displayed.

FIG. 6 is a diagram showing an example of graph display of power consumption by the display apparatus 2.

A graph G2 of FIG. 6 is provided for graphically displaying daily power consumption, in which a rectangle L1 surrounded by lines of a reference clock-in time K1, a reference clock-out time K2, target power consumption PP and power consumption 0 is overlaid and displayed on graph display as a target power consumption area. Note that, on the graph G2, reference power consumption SP is also overlaid and displayed.

A user views such display, and thereby is able to recognize a time zone of larger power consumption compared to the target power consumption, for example, so that it is possible to easily grasp the time zone for which power consumption should be suppressed.

Note that, in the case of having a day when the clock-in/out time calculation portion 20a is not able to estimate a clock-in time and a clock-out time, an applicable day is estimated as a day of absence. Then in the case of having a day of absence, the clock-in/out time calculation portion 20a calculates an average clock-in time and an average clock-out time excluding the day of absence.

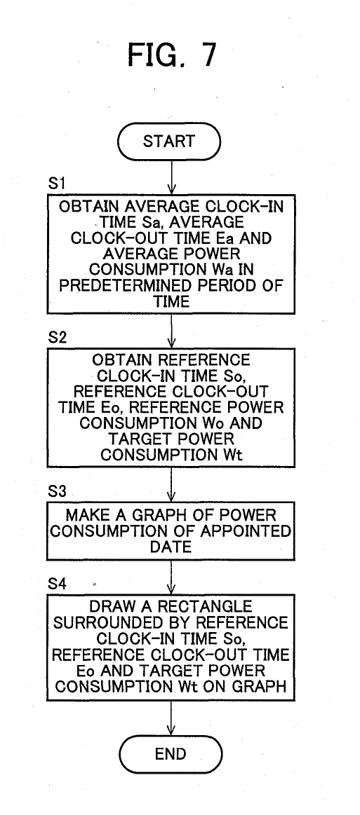

FIG. 7 is a flowchart explaining an example of graph display processing by the display apparatus 2.

In the display apparatus 2, when an instruction to graphically display power consumption of a certain power measurement tap 3 is received via the tablet 26, the clock-in/out time calculation portion 20a estimates an clock-in time and a clock-out time of a worker involved in the power measurement tap 3 based on a change in daily power consumption with reference to aggregate power consumption data to calculate (1) an average clock-in time Sa and (2) an average clock-out time Ea in a predetermined period of time, while the average power calculation portion 20b calculates (3) daily average power consumption Wa in the predetermined period of time of the power measurement tap 3 based on the aggregate power consumption data (step S1), then the process goes to step S2. The predetermined period of time is decided by a user or automatically from among the period of times for collecting power consumption, and for example, in an example of FIG. 5, four days are provided as a period of time for obtaining power consumption data, for example, first two day of which are thus set as the above-described predetermined period of time.

At step S2, the average power calculation portion 20b decides (4) a reference clock-in time So and (5) a reference clock-out time Eo from the average clock-in time Sa, the average clock-out time Ea and the average power consumption Wa to calculate (6) average power consumption, that is, reference power consumption Wo, while the target power calculation portion 20c calculates (7) target power consumption Wt from the reference power consumption Wo. The above items (4) to (7) are obtained by, for example, the following formulas.

Reference clock-in time So=average clock-in time Sa (4)

Reference clock-out time Eo=average clock-out time Ea (5)

Reference power consumption Wo=average power consumption Wa/(average clock-out time−average clock-in time) (6)

Target power consumption Wt=reference power consumption Wo×(1−target reduction rate Z) (7)

In this example, the reference clock-in time So, the reference clock-out time Eo, the average clock-in time Sa and the average clock-out time Ea are used as they are. Modifications may be added such that the average clock-out time later than a predetermined time is accelerated to the time, or the average clock-in time earlier than a predetermined time is delayed to the time, in some cases. The reference power consumption Wo (unit: W) is obtained by dividing the average power consumption Wa (unit: Wh) by (average clock-out time−average clock-in time), that is, average working hours. The target power consumption Wt is a numerical value obtained by taking a predetermined target reduction rate off the reference power consumption Wo.

At step S3, a graph of power consumption of an appointed date is made on the display 27, and at step S4, a rectangle surrounded by the reference clock-in time So, the reference clock-out time Eo and the target power consumption Wt, and the reference power consumption are drawn on the graph, then the process is finished.

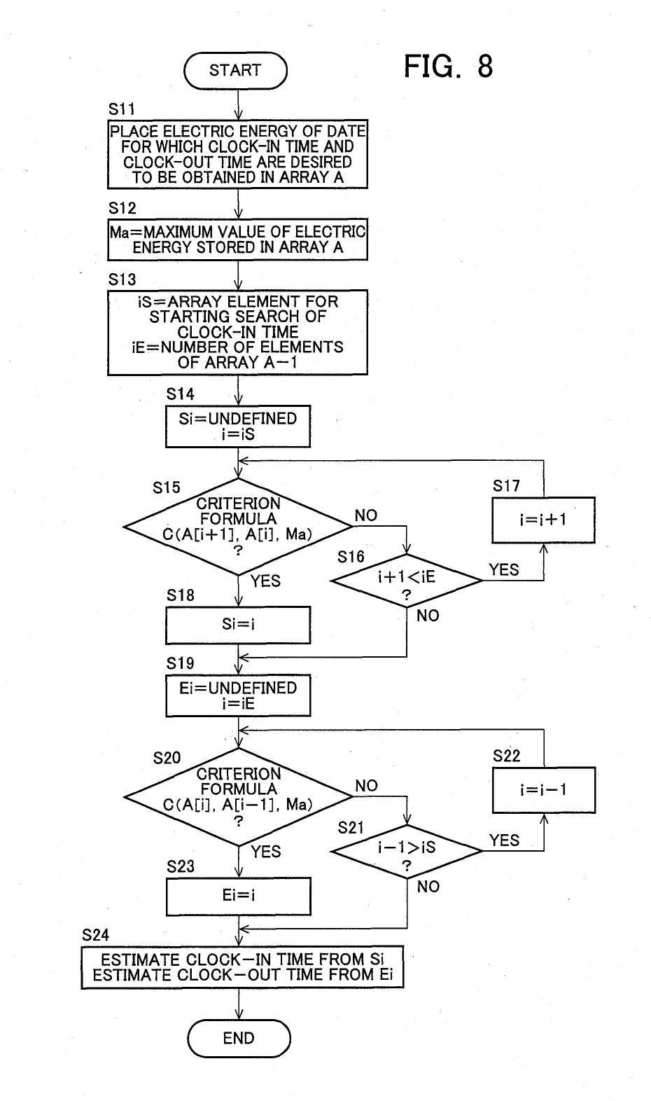

FIG. 8 is a flowchart explaining an example of estimation processing of a clock-in time and a clock-out time performed by the clock-in/out time calculation portion 20a.

The clock-in/out time calculation portion 20a first places electric energy for each time zone of the day for which a clock-in time and a clock-out time are desired to be obtained in an array A (step S11). In this example, a method of storing electric energy for each time zone in the array A is provided as a method of sequentially placing an electric energy therein from an earlier time zone.

At step S12, a maximum value of the electric energy that is stored in the array A is obtained as Ma, and the process goes to step S13.

At step S13, an array element for starting to search a clock-in time is iS, and the number of elements of the array A−1=iE. In a case where daily power measurement is started at 0:00 a.m., supposed is also the case of getting a next day at 0:00 a.m. directly from attendance of the previous day. In such a case, the time for starting search of a clock-in time may be set to about 3:00 a.m. The time for starting search of a clock-in time may be set depending on a situation of a workplace. In this example, because of setting a method of placing in the array A electricity in the sequence that is earlier to be obtained, in the case of deciding the time for starting search of a clock-in time, a value of the array element iS is also obtained. The number of elements of the array A is decided depending on a time interval for aggregating electric energy. For example, in the case of aggregating for each hour as examples of FIG. 4A and FIG. 4B, the number of elements of the array is 24, and iE is 23. After iS and iE are set, the process goes to step S14.

At step S14, an array element Si corresponding to a clock-in time is undefined, and a variable i for searching a clock-in time is iS, then the process goes to step S15. At step S15, a criterion formula C described below is used to determine whether or not a current array element corresponds to a clock-in time. In the case of correspondence (in the case of Yes), the process goes to step S18, and in the case of no correspondence, the process goes to step S16.

The criterion formula C is provided as follows, for example.

Criterion formula C(a1,a2,ma)=in the case of ma<Mn, No in the case of ma≧Mn and |a1−a2|>ma×R, Yes in the case of ma≧Mn and |a1−a2|≧ma×R, No

Where, a1 and a2 are arguments of the criterion formula C, to each of which, an element of the array A, that is, electric energy in a certain time zone is applicable. ma is an argument of the criterion formula C, to which, maximum electric energy Ma is applicable. A constant Mn is a threshold with respect to maximum electric energy. The maximum electric energy Ma smaller than Mn by a first conditional expression of the criterion formula C results in No. A value of Mn may be set to a value sufficiently smaller than electricity when equipment connected to the power measurement tap 3 is powered on. A constant R is a rate as to whether to regard as attendance in the case of measuring electricity a certain percentage larger than maximum electricity, and may be decided by adjusting values between 0 and 1.

At step S15, an argument of the criterion formula C is a1=A[i+1], a2=A [i], and ma=Ma.

Accordingly, a value of the criterion formula C is,
in the case of Ma<Mn, No;
in the case of Ma≧Mn and |A[i+1]−A [i]|>Ma×R, Yes; and
in the case of Ma≧Mn and |A[i+1]−A [i]|≦Ma×R, No.

At step S16, determination is made on whether to be i+1<iE. In the case of yes, a value of i is incremented by one at step S17, and the process returns to step S15. In the case of No, the process goes to step S19.

At step S18, i is assigned to S1, and the process goes to step S19.

At step S19, an array element Ei corresponding to a clock-out time is undefined, and a variable i for searching a clock-out time is iE, then the process goes to step S20.

At step S20, the criterion formula C is used to determine whether or not a current array element corresponds to a clock-out time. In the case of correspondence (in the case of Yes), the process goes to step S23, and in the case of no correspondence, the process goes to step S21.

At step S20, an argument of the criterion formula C is a1=A [i], a2=A [i−1] and ma=Ma.

Accordingly, a value of the criterion formula C is,

in the case of Ma<Mn, No;

in the case of Ma≧Mn and |A[i]−A[i−1]|>Ma×R, Yes; and

in the case of Ma Mn and |A[i]−A[i−1]|≦Ma×R, No.

At step S21, determination is made on whether to be i−1>iS. In the case of yes, the value of i is decremented by one at step S22, and the process returns to step S20. In the case of No, the process goes to step S24.

At step S23, i is assigned to Ei, and the process goes to step S24.

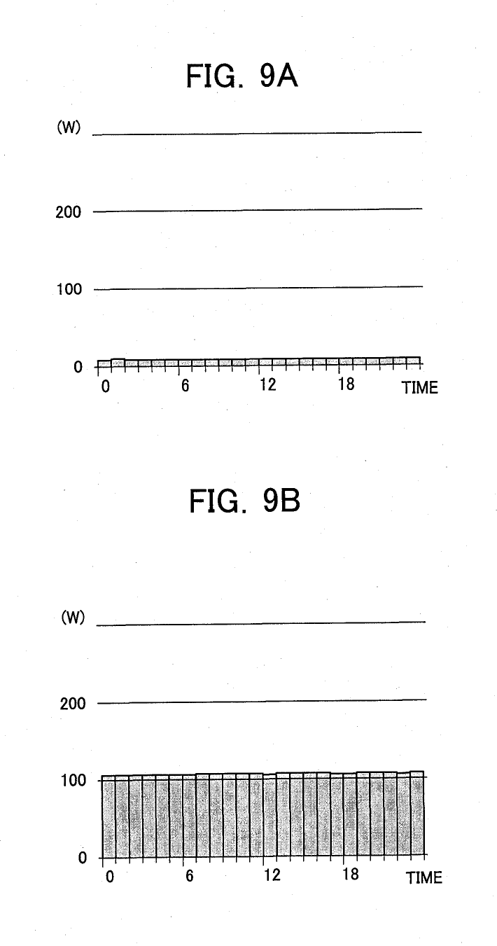

At step S24, a time zone corresponding to Si is estimated as a clock-in time, and a time zone corresponding to Ei is estimated as a clock-out time. At the time, Si and Ei may be undefined in some cases. In such a case, the criterion formula C results in No all the time. Such an example of electricity is shown in FIG. 9A, and FIG. 9B. FIG. 9A is an example in which the maximum electric energy Ma is smaller than Mn. FIG. 9B shows a case where, even in the case of the maximum electric energy Ma>Mn, a change of electricity is smaller than Ma X R, and a criterion formula results in No.

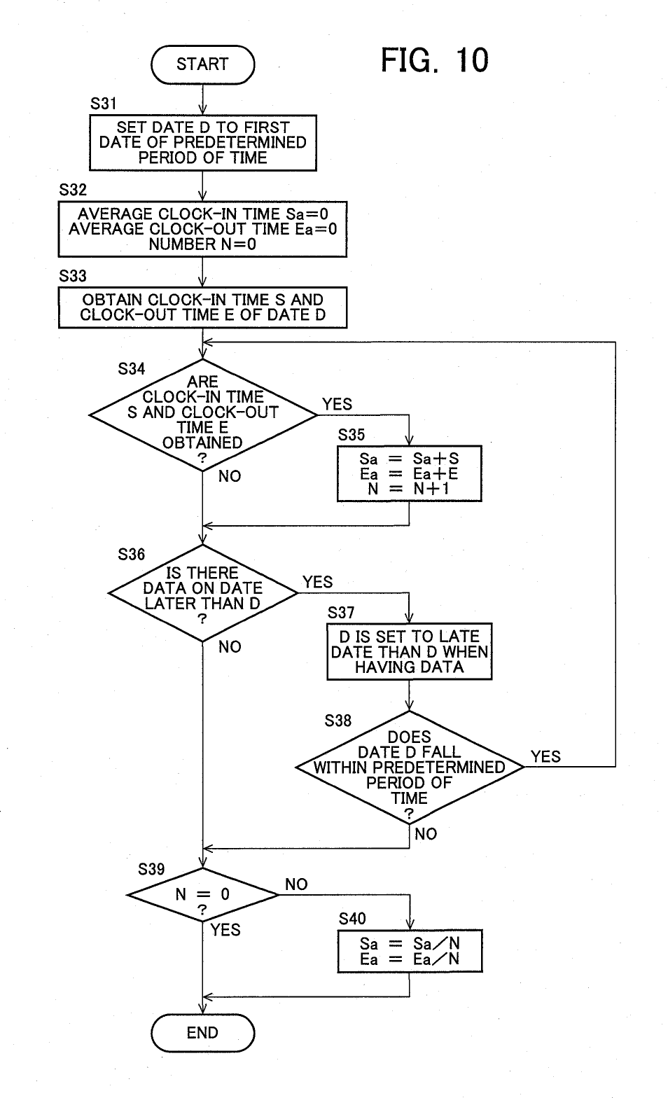

FIG. 10 is a flowchart explaining an example of calculation processing of an average clock-in time and an average clock-out time performed by the clock-in/out time calculation portion 20a.

At step S31, the clock-in/out time calculation portion 20a sets a date D to a first date of a predetermined period of time, and the process goes to step S32.

At step S32, average clock-in time Sa=0, average clock-out time Ea=0 and a number N=0 are set, and the process goes to step S33.

At step S33, a clock-in time S and a clock-out time E of the date D are estimated, and the process goes to step S34. A method of estimating the clock-in time S and the clock-out time E is provided as explained with use of FIG. 8 described above, for example.

At step S34, determination is made on whether the clock-in time S and the clock-out time E are estimated. In the case of Yes, the process goes to step S35. In the case of No, the process goes to step S36.

At step S35, in order to obtain an average, Sa=Sa+S, Ea=Ea+E, and N=N+1 are set, and the process goes to step S36.

At step S36, determination is made on whether to have data on a date later than D. In the case of Yes, the process goes to step S37. In the case of No, the process goes to step S39.

At step S37, D is set to a later date than D when having data, and the process goes to step S38.

At step S38, the date D is determined whether to fall within a predetermined period of time. In the case of Yes, the process goes to step S33. In the case of No, the process goes to step S39.

At step S39, determination is made on whether N is 0. In the case of No, the process goes to step S40. In the case of Yes, the process is finished.

At step S40, Sa=Sa/N and Ea=Ea/N are set to calculate an average clock-in time and an average clock-out time, then the process is finished.

In the above-described examples, a load is supposed to be one or more of an electronic device which is connected to one power measurement tap, however, the present invention is applicable to a case where a group of electronic devices which are connected to a plurality of power measurement taps serves as a load, or a case where one of a plurality of electronic devices connected to one power measurement tap serves as a load.

Moreover, as described above, a power measurement tap generates power consumption data in which electricity that is supplied to the load is measured for each predetermined period of time (for example, per second) over a certain period of time (for example, one day) with use of an ammeter for sending to a display apparatus, however, data on electricity measured for each predetermined period of time described above may be sent to the display apparatus for each of the measurement so that the display apparatus generates the above-described power consumption data based on the data.

Note that, the disclosed embodiments are illustration in all respects and should not be limited. The scope of the present invention is indicated by claims rather than the above-described description, and intended to embrace all modifications within the meaning equivalent to and the scope of the claims.

Hereinabove, in the present invention, in the case of displaying electric power consumption, a reference clock-in time and a reference clock-out time are indicated on a graph, thus making it possible to understand at a glance power consumption in a time other than the reference clock-in time and the reference clock-out time. Accordingly, it is easy to understand a point to suppress electricity usage such as midnight electricity usage and electricity usage for long overtime hours. Further, a target power consumption range is automatically calculated, thus eliminating the need for time and effort in target setting.

1. A power consumption display method comprising the steps of:
estimating a clock-in time and a clock-out time of a worker involved in a load from a change in power consumption per day based on power consumption data which is obtained by measuring electric power supplied to the load for a certain period to calculate an average clock-in time and an average clock-out time of the worker in a predetermined period of time using the estimated value;
calculating average power consumption of the load during working hours a day in the predetermined period of time based on the power consumption data as well as the average clock-in time and the average clock-out time;
calculating target power consumption of the load reduced at a predetermined rate from the average power consumption; and
graphically displaying a measurement value of power consumption per day of the load together with the average clock-in time and the average clock-out time as well as the target power consumption that are calculated.

2. A power consumption display apparatus comprising:
a clock-in/out time calculation portion for estimating a clock-in time and a clock-out time of a worker involved in a load from a change in power consumption per day based on power consumption data which is obtained by measuring electric power supplied to the load for a certain period to calculate an average clock-in time and an average clock-out time of the worker in a predetermined period of time using the estimated value;
an average power calculation portion for calculating average power consumption of the load during working hours a day in the predetermined period of time based on the power consumption data as well as the average clock-in time and the average clock-out time;
a target power calculation portion for calculating target power consumption of the load reduced at a predetermined rate from the average power consumption; and
a display portion for graphically displaying a measurement value of power consumption per day of the load together with the average clock-in time and the average clock-out time as well as the target power consumption that are calculated.
